(19) United States
(12) Patent Application Publication
(10) Pub. No.: US 2013/0241583 A1
(43) Pub. Date: Sep. 19, 2013

(54) DEVICE FOR TESTING SHORT CIRCUIT PROTECTION FUNCTION OF POWER SUPPLY

(71) Applicant: CHI-WEN CHEN, Tu-Cheng (TW)

(72) Inventor: CHI-WEN CHEN, Tu-Cheng (TW)

(73) Assignee: HON HAI PRECISION INDUSTRY CO., LTD., Tu-Cheng (TW)

(21) Appl. No.: 13/609,635

(22) Filed: Sep. 11, 2012

(30) Foreign Application Priority Data
Mar. 19, 2012 (TW) 101204881

(51) Int. Cl. G01R 31/327

(52) U.S. Cl. 324/750.01

(57) ABSTRACT

A device for testing short circuit protection functions of a plurality power supply units of a power supply includes a short circuit control module, a controller and an oscilloscope. The short circuit control module includes a number of driving circuits and a number of short circuits corresponding to the driving circuits. Each driving circuit is electrically connected to one of the power supply units by the corresponding short circuit. The controller is electrically connected to the driving circuits. The controller controls one or more of the driving circuits to drive the corresponding short circuits to short-circuit the corresponding power supply units. The oscilloscope is electrically connected to each power supply unit. The oscilloscope displays waveforms of output voltage of the short-circuit power supply units.

### BACKGROUND

1. Technical Field

The disclosure generally relates to testing devices, and particularly to a device for testing a short circuit protection function of a power supply.

2. Description of Related Art

During manufacture, a short circuit protection function of a power supply commonly needs to be tested. In a short circuit protection function of the power supply testing method, the power supply is electrically connected to a load via a testing fixture which converts a voltage output from the power supply into a preset voltage for the load. A mechanical switch is electrically connected between the load and the testing fixture. Thus, the power supply can be short-circuited by manually turning on the mechanical switch to test the short circuit protection function.

However, in above method, the mechanical switch may generate noise while being turned on. The noise may interfere to a test result such as waveform of the voltage output form the power supply shown by an oscilloscope and negatively influence the test result.

Therefore, there is room for improvement within the art.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the disclosure.

FIG. 1 is a block diagram of a device for testing short circuit protection function of a power supply, according to an exemplary embodiment of the disclosure.

FIG. 2 is a partial circuit diagram of the device in FIG. 1, according to an exemplary embodiment of the disclosure.

### DETAILED DESCRIPTION

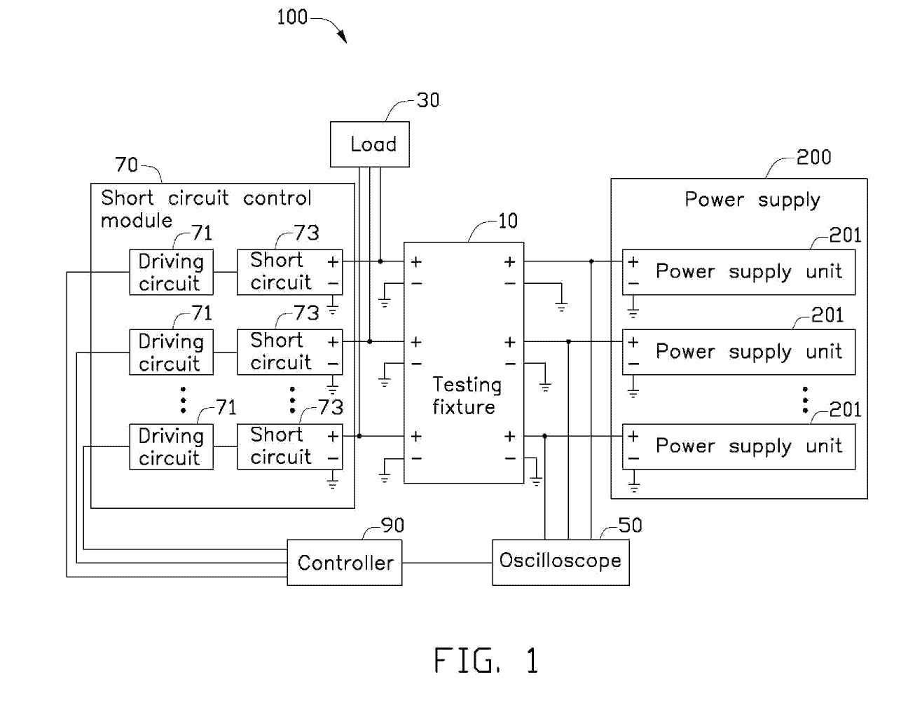

FIG. 1 is a block diagram of a device 100 for testing short circuit protection function of a power supply 200, according to an exemplary embodiment of the disclosure. The device 100 includes a testing fixture 10, a load 30, an oscilloscope 50, a short circuit control module 70, and a controller 90.

In one embodiment, the power supply 200 includes a plurality of groups of power supply units 201. Each power supply unit 201 includes a group of a positive power supply terminal and a negative power supply terminal. The positive power supply terminal of each power supply unit 20 is electrically connected to the testing fixture 10. The negative power supply terminal of each power supply unit 20 is grounded. In this embodiment, the testing device 100 can test the short circuit protection functions of the power supply units 201 simultaneously.

The testing fixture 10 is electrically connected between the power supply 200 and the load 30. The testing fixture 10 converts a voltage output from each power supply unit 201 into a preset voltage and outputs the converted voltage to the load 30. The testing fixture 10 also can connect the power supply 200 to other testing apparatuses. In this embodiment, the testing fixture 10 includes a plurality of input terminal groups and a plurality of output terminal groups corresponding to the input terminal groups.

Each input terminal group includes a positive input terminal and a negative input terminal Each output terminal group includes a positive output terminal and a negative output terminal The input terminal groups correspond to the power supply units 201. Each positive input terminal is electrically connected to one of the corresponding power supply unit 201. Each negative input terminal is grounded. Each positive output terminal is electrically connected to the load 30. Each negative output terminal is grounded. When one group of the positive output terminal and the negative output terminal is short-circuited, the corresponding power supply unit 201 is short-circuited and the short circuit protection function thereof can be tested.

The load 30 is configured for providing different loads to the power supply 200.

The oscilloscope 50 is electrically connected to the positive power supply terminal of each power supply units 201 and configured for displaying waveforms of output voltages of each power supply unit 201. When a particular power supply unit 201 is short-circuited, the short circuit protection function of the power supply unit 201 can be tested by adjusting whether the output voltage of the power supply unit 201 is decreased to about zero from the oscilloscope 50.

The oscilloscope 50 may include a plurality of output channels corresponding to one of the power supply units 201. Each output channel displays the waveform of the output voltage from one of the power supply unit 201.

The short circuit control module 70 includes a plurality of driving circuits 71 and a plurality of short circuits 73 corresponding to the driving circuits 71. Each driving circuit 71 is electrically connected to one of the corresponding short circuit 73 in series between one of the positive output terminals of the testing fixture 10 and the controller 90. Each driving circuit 71 drives the corresponding short circuit 73 to short-circuit the corresponding power supply unit 201 by controlling of the controller 90.

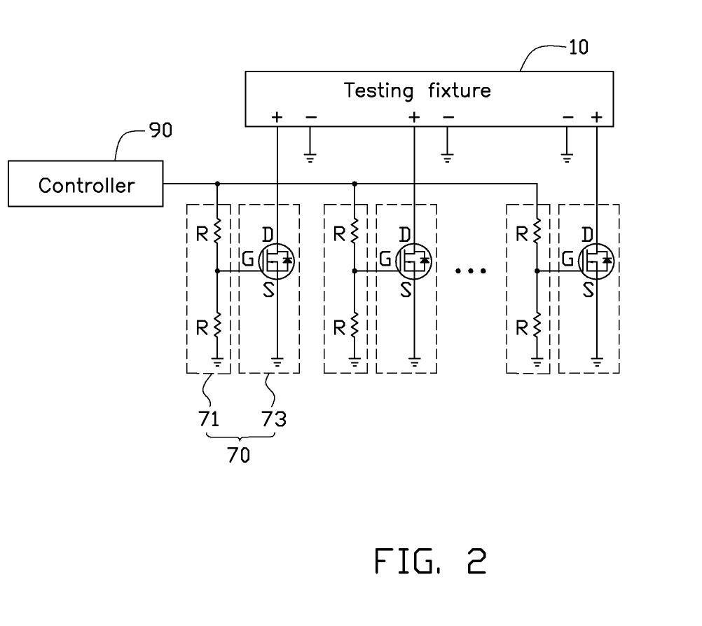

Referring to FIG. 2, in one exemplary embodiment, each driving circuit 71 includes two voltage dividing resistors R connected in series. Each of the resistors R is electrically connected between the controller 90 and ground. Each short circuit 73 is a switch such as a transistor or a relay. In this embodiment, each short circuit 73 is a metal-oxide-semiconductor field-effect transistor (MOSFET) as one example. A gate G of each short circuit 73 is electrically connected between the two resistors R. A drain D of each short circuit is 73 electrically connected to the positive terminal. A source S of each short circuit 73 is grounded.

The controller 90 controls one or more of the power supply units 201 to be short-circuited by the short circuit control module 70. In one embodiment, the controller 90 sends a control signal such as a high level signal (i.e. logic 1) to the driving circuit 71, the corresponding connected short circuit 73 is turned on, and the corresponding power supply unit 201 is short-circuited. Meanwhile, the controller 90 controls the oscilloscope 50 to display the waveform of the output voltage of the short-circuited power supply unit 201. The short circuit protection function of the power supply unit 201 can be tested from the waveform. The controller 90 may be a computer or a single chip.

To test the short circuit protection functions of the power supply units 201, the positive power supply terminal of each power supply units 201 is electrically connected to one of the positive input terminals of the testing fixture 10 and the oscilloscope 50. The negative power supply terminal of each power supply units 201 is grounded. If some of the power supply units 201 need to be tested, the controller 90 sends the high level voltage to one or more of the driving circuits 71 corresponding to the power supply units 201. The driving circuit 71 drives the corresponding short circuit 73 to turn on so that the power supply units 201 is short-circuited by the short circuit 73. The short circuit protection function of some of the power supply units 201 can be test from the waveform shown by the oscilloscope 50 directly.

The device 100 controls the short circuit control module 70 to automatically short-circuit the power supply units 201 by the controller 90 so that the device 100 can have a higher degree of testing accuracy and testing efficiency than a mechanical testing method.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A device for testing short circuit protection functions of a plurality of power supply units of a power supply, the device comprising:
a short circuit control module comprising a plurality of driving circuits and a plurality of short circuits corresponding to the driving circuits, each driving circuit electrically connected to one of the power supply units by the corresponding short circuit;
a controller electrically connected to the driving circuits, the controller controlling one or more of the driving circuits to drive the corresponding short circuits to short-circuit the corresponding power supply units; and
an oscilloscope electrically connected to each of the power supply units, the oscilloscope displaying waveforms of output voltage of the short-circuit power supply units.

2. The device of claim 1, further comprising a testing fixture, wherein the testing fixture comprises a plurality of input terminal groups and a plurality of output terminal groups corresponding to the input terminal groups, the input terminal groups correspond to the power supply units, each input terminal group is electrically connected one of the power supply units, each output terminal group is electrically connected one of the short circuits.

3. The device of claim 1, further comprising a load, wherein the load is electrically connected to the power supply to provide different loads for the power supply.

4. The device of claim 2, wherein each short circuit is a metal-oxide-semiconductor field-effect transistor (MOSFET), a gate of each short circuit is electrically connected to the driving circuit, a drain of each short circuit is electrically connected to one of output terminal of the testing fixture, a source of each short circuit is grounded.

5. The device of claim 4, wherein each driving circuit comprises two resistors connected in series, the connected resistors connected between the controller and ground, a node between the resistors is connected to the gate of the corresponding short circuit.

6. The device of claim 4, wherein the oscilloscope comprises a plurality of output channels respectively corresponding to one of the power supply unit, each output channel displays the waveform of the output voltage from one of the short-circuited power supply unit.

7. A device for testing short circuit protection functions of a plurality of power supply units of a power supply, the device comprising:
a short circuit control module comprising a plurality of driving circuits and a plurality of switches corresponding to the driving circuits, each driving circuit electrically connected to one of the power supply units by the corresponding switch;
a controller electrically connected to the driving circuits, the controller controlling one or more of the driving circuits to turn on the corresponding switches and short-circuit the corresponding power supply units; and
an oscilloscope electrically connected to each of the power supply units, the oscilloscope displaying waveforms of output voltage of the short-circuit power supply units.

8. The device of claim 7, further comprising a testing fixture, wherein the testing fixture comprises a plurality of input terminal groups and a plurality of output terminal groups corresponding to the input terminal groups, the input terminal groups correspond to the power supply units, each input terminal group is electrically connected one of the power supply units, each output terminal group is electrically connected one of the switches.

9. The device of claim 7, further comprising a load, wherein the load is electrically connected to the power supply to provide different loads for the power supply.

10. The device of claim 8, wherein each switch is a metal-oxide-semiconductor field-effect transistor (MOSFET), a gate of each short circuit is electrically connected to the driving circuit, a drain of each short circuit is electrically connected to one of output terminal of the testing fixture, a source of each short circuit is grounded.

11. The device of claim 10, wherein each driving circuit comprises two resistors connected in series, the connected resistors connected between the controller and ground, a node between the resistors is connected to the gate of the corresponding switch.

12. The device of claim 7, wherein the oscilloscope comprises a plurality of output channels corresponding to one of the power supply unit, each output channel displays the waveform of the output voltage from one of the short-circuited power supply unit.
